(19) United States
(12) Patent Application Publication
(10) Pub. No.: US 2006/0284313 A1
(43) Pub. Date: Dec. 21, 2006

(54) Low stress chip attachment with shape memory materials

(76) Inventor: Yongqian Wang, Gilbert, AZ (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 11/154,099

(22) Filed: Jun. 15, 2005

(51) Int. Cl. H01L 23/48

(52) U.S. Cl. 257/737

(57) ABSTRACT

Some embodiments of the present invention include low stress chip attachment with shape memory materials.

### TECHNICAL FIELD

Embodiments of the invention relate to semiconductor packaging. In particular, embodiments of the invention relate to methods and apparatus for semiconductor chip attachment.

### BACKGROUND

After a microelectronic chip or die has been manufactured, it is typically packaged before it is sold. The package may provide electrical connections between the chip's internal circuitry and the exterior environment. In one package system, a chip may be flip-chip connected to a substrate. In a flip-chip package, electrical leads on the die are distributed on its active surface and the active surface is electrically connected to corresponding leads on a substrate. Flip-chip packaging may provide improved performance, such as short leads, low inductance, and high lead density. Often, in forming a flip-chip package, the die, substrate, and leads are under stresses due to heating and cooling the package and from other sources. Such stresses may cause decreased performance of the die and damage, such as delamination or cracking, to the die or substrate.

### BRIEF DESCRIPTION OF THE DRAWINGS

The invention is illustrated by way of example and not by way of limitation in the figures of the accompanying drawings, in which the like references indicate similar elements and in which:

FIG. 1 illustrates a stress-strain diagram for a shape memory material in accordance with one embodiment of the present invention.

FIG. 2 illustrates a stress-strain diagram for a shape memory material in accordance with one embodiment of the present invention.

FIG. 3 illustrates a stress-strain diagram for a shape memory material in accordance with one embodiment of the present invention.

FIG. 4 illustrates a yield stress-temperature diagram for a shape memory material in accordance with one embodiment of the present invention.

FIGS. 5A-5C illustrate cross sectional type views of an apparatus and method in accordance with one embodiment of the present invention.

FIG. 6 illustrates a cross sectional type view of an apparatus in accordance with one embodiment of the present invention.

FIG. 6 illustrates a cross sectional type view of an apparatus in accordance with one embodiment of the present invention.

FIG. 7 illustrates a cross sectional type view of an apparatus in accordance with one embodiment of the present invention.

FIG. 8 illustrates a cross sectional type view of an apparatus in accordance with one embodiment of the present invention.

FIG. 9 illustrates a schematic of a system in accordance with one embodiment of the present invention.

### DETAILED DESCRIPTION

In the following description, various embodiments relating to semiconductor packaging will be described. However, various embodiments may be practiced without one or more of the specific details, or with other methods, materials, or components. In other instances, well-known structures, materials, or operations are not shown or described in detail to avoid obscuring aspects of various embodiments of the invention. Similarly, for purposes of explanation, specific numbers, materials, and configurations are set forth in order to provide a thorough understanding of the invention. Nevertheless, the invention may be practiced without specific details. Furthermore, it is understood that the various embodiments shown in the figures are illustrative representations and are not necessarily drawn to scale.

Various operations will be described as multiple discrete operations in turn. However, the order of description should not be construed as to imply that these operations are necessarily order dependent. In particular, these operations need not be performed in the order of presentation.

Semiconductor packaging quality and reliability may be enhanced by reducing stresses in the package, including in the die, substrate, or joints. In particular, stresses may be reduced by using a shape memory material to electrically connect the die and the substrate. As discussed below, in comparison to other materials, shape memory materials may provide the advantages of greater deformation under constant loading, full deformation recovery, negative temperature dependence of yield stress, and being more compliant at room temperature.

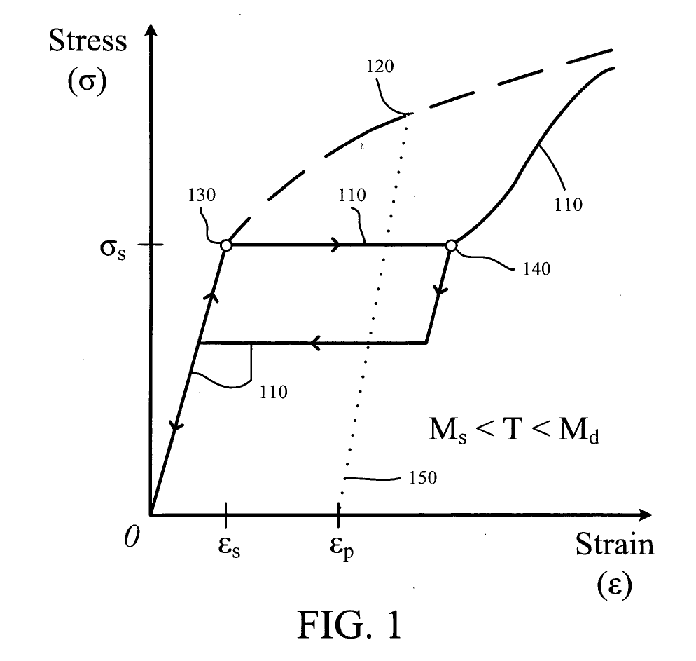

FIG. 1 illustrates a stress-strain diagram for a typical metal or alloy and a shape memory material at a temperature (T) between temperatures Mₛ and M_{d}. Generally, in a stress-strain diagram, the stress is defined as the force per unit area applied to the sample and the strain may be a measure of the sample's deformation under that stress. Temperatures Mₛ and M_{d} may be characteristic temperatures of the shape memory material. Mₛ may be the martensitic temperature around which the yield stress of the shape memory material begins to increase with decreasing temperature. M_{d} may be a characteristic temperature at which the yield stress of the shape memory material begins to decrease with decreasing temperature.

FIG. 1 illustrates shape memory material curve 110 (solid line), typical metal or alloy curve 120 (dashed line), yield point 130, point 140, and typical residual strain line 150 (dotted line). As illustrated in FIG. 1, at a stress less than yield point 130, both the shape memory material and the typical metal or alloy may exhibit elastic deformation (the solid shape memory material curve 110 covers the dashed typical metal or alloy curve 120 in the elastic deformation region in FIG. 1). In the elastic deformation region, the shape memory material and the typical metal or alloy may exhibit an approximately linear stress-strain pattern and the strain returns to zero after the stress returns to zero (as is indicated by the arrow). That is, when a stress is unloaded in the elastic region, there is no, or little, residual deformation. Typically, the strain limit (εₛ) for a typical metal or alloy may be approximately 1%.

As the stress increases above the yield point 130, the stress-strain characteristics of the typical metal or alloy and the shape memory material may be markedly different. In that region, the typical metal or alloy may enter a plastic flow regime, where stress increases with strain and there may be a permanent deformation upon unloading (for example, by following typical residual strain line 150 to point εₚ). In contrast, the shape memory material may exhibit a stress plateau between yield point 130 and point 140. In the plateau region, the stress may remain approximately constant as strain increases. That is, the shape memory material may not exhibit work hardening in the plateau region. Further, at any point in the plateau region, upon unloading, the stress-strain may decrease to zero (following a path similar to the path indicated by arrows in FIG. 1). That is, for the shape memory material in the plateau region, when a stress is unloaded, there is no, or little, residual deformation. At a stress-strain above the stress-strain at point 140, the shape memory material may exhibit work hardening and may not return to a strain of zero upon unloading.

In some embodiments, the strain at point 140 may be a maximum strain at which the shape memory material returns to a strain of zero upon unloading. In an embodiment, the maximum strain may be up to approximately 8%. In another embodiment, the maximum strain may be in the range of about 1 to 6%. In an embodiment, the maximum strain may be in the range of about 3 to 8%.

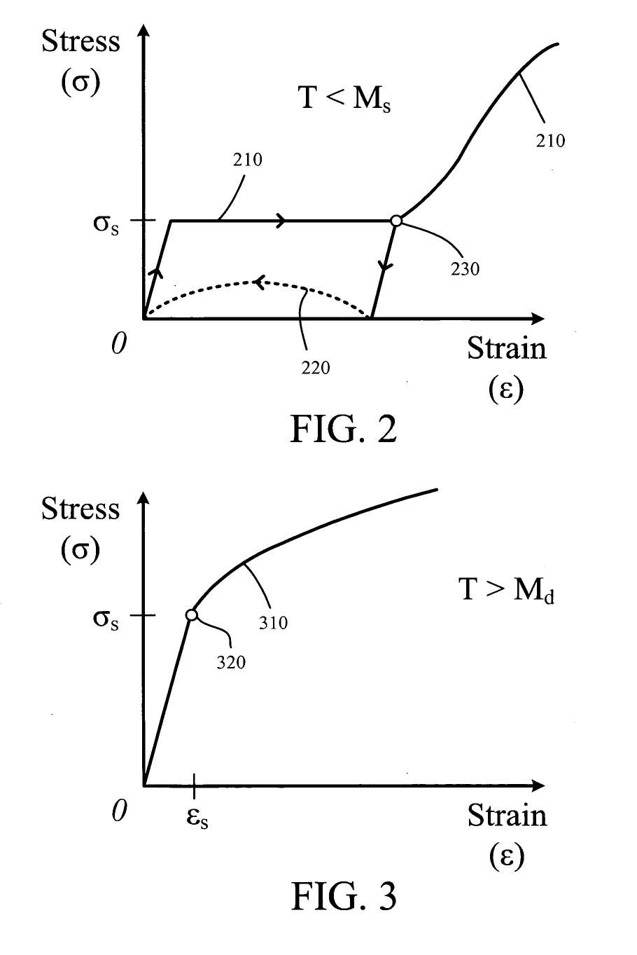

FIG. 2 illustrates a stress-strain diagram for a shape memory material at a temperature (T) below characteristic temperature Mₛ. FIG. 2 illustrates shape memory material curve 210 (solid line), representative heating path 220 (dotted line), and point 230. As illustrated in FIG. 2, the shape memory material may exhibit a stress plateau at σₛ similar to the stress plateau discussed with reference to FIG. 1. In the plateau region, the stress may remain approximately constant. As illustrated in FIG. 2, in the plateau region, upon unloading, the strain may not go to zero and there may be a residual deformation. However, when heated above characteristic temperature M_{f} (indicated by heating path 220 in FIG. 2), the strain may go to zero and the deformation may be eliminated such that there is little or no residual deformation. In an embodiment, temperature M_{f} may be in the range of about 20 to 50° C. greater than Mₛ. In another embodiment, the temperature required to recover the deformation may be in the range of about 50 to 80° C. greater than Mₛ. In another embodiment, the temperature required to recover the deformation may be in the range of about 30 to 60° C. greater than Mₛ.

In some embodiments, the strain at point 230 may be a maximum strain at which the deformation may be recovered upon heating. In an embodiment, the maximum strain may be up to approximately 8%. In another embodiment, the maximum strain may be in the range of about 1 to 6%. In another embodiment, the maximum strain may be in the range of about 3 to 8%.

FIG. 3 illustrates a stress-strain diagram for a shape memory material at a temperature (T) above characteristic temperature M_{d}. FIG. 3 illustrates shape memory material curve 310 and yield point 320. As illustrated in FIG. 3, above characteristic temperature M_{d}, the shape memory material may exhibit a stress-strain pattern similar to that of a typical metal or alloy (as illustrated in FIG. 1). At a stress below yield point 320, the shape memory material may exhibit linear elastic deformation. At a stress above yield point 320, the shape memory material may exhibit plastic deformation including work hardening and deformation may not be recoverable upon unloading.

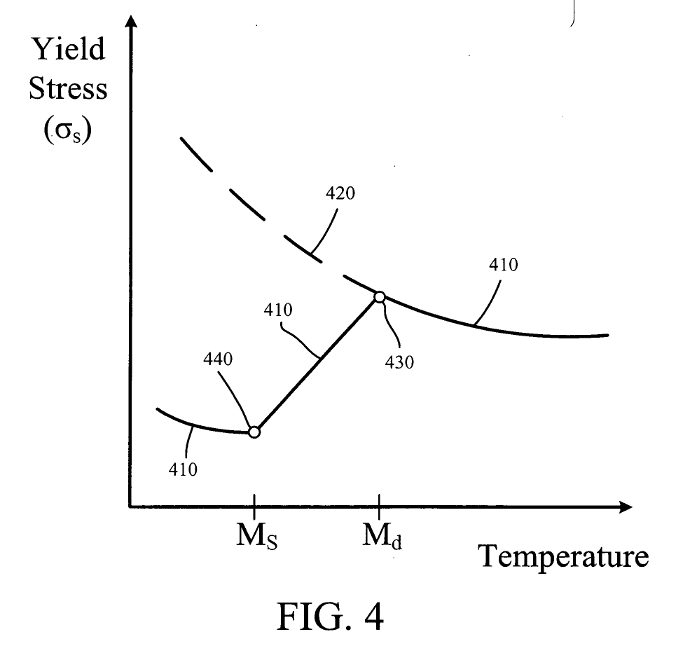

FIG. 4 illustrates a yield stress (or stress plateau amplitude)-temperature diagram for a typical metal or alloy and a shape memory material. FIG. 4 illustrates shape memory material curve 410 (solid line), typical metal or alloy curve 420 (dashed line), M_{d} temperature point 430, and Mₛ temperature point 440. As illustrated in FIG. 4, above temperature M_{d}, the typical metal or alloy and the shape memory material may exhibit similar characteristics (the solid shape memory material curve 410 covers the dashed typical metal or alloy curve 420 in FIG. 4). In the region above temperature M_{d}, both the typical metal or alloy and the shape memory material may exhibit increasing yield stress with decreasing temperature. That is, they may become less compliant as they become cooler.

However, below temperature M_{d}, the characteristics may be different. Below temperature M_{d}, the yield stress of the typical metal or alloy may continue to increase as temperature decreases. In contrast, the yield stress of the shape memory material may decrease with decreasing temperature between temperature M_{d} and temperature Mₛ and the shape memory material may become more compliant as it cools. At a temperature below Mₛ, the yield stress of the shape memory material may begin to increase with decreasing temperature. In an embodiment, the minimum yield stress may be around temperature Mₛ and the minimum yield stress may be as low as about 12-20 MPa.

As is further discussed below, the characteristics of shape memory materials described with reference to FIGS. 1-4 may be used to reduce stresses in microelectronic package systems. In the embodiments that follow, the shape memory material may be any suitable shape memory material, including shape memory alloys, shape memory polymers, shape memory ceramics, and others. In an embodiment, the shape memory material may include Nitinol, an alloy of Nickel and Titanium. In another embodiment, the shape memory material may include a Copper shape memory alloy. In an embodiment, the shape memory material may include a Copper shape memory alloy including Zinc. In another embodiment, the shape memory material may include a Copper shape memory alloy including Aluminum.

In other embodiments, the shape memory material may include a composite of two or more materials. In an embodiment, the composite may include a metal or solder with embedded shape memory material powders or fibers. In another embodiment, the composite may include a matrix metal and shape memory material powders or fibers. In various embodiments, the composite may include Copper, Tin, or Gold and shape memory material powder or fibers. In some embodiments, the shape memory powders or fibers may include Nitinol or Copper shape memory alloys. The shape memory material powders or fibers may be of any suitable weight percentage. In an embodiment, the shape memory material may be in the range of about 0-80 wt %. In another embodiment, the shape memory material may be in the range of about 40-80 wt %. In an embodiment, the shape memory material may be in the range of about 10-80 wt %.

In another embodiment, the shape memory material may include a solder and imbedded shape memory material powders or fibers. The solder may be any suitable material and the shape memory material may be of any suitable weight percentage. In an embodiment, the shape memory material may be in the range of about 0-80 wt %. In another embodiment, the shape memory material may be in the range of about 40-80 wt %. In an embodiment, the shape memory material may be in the range of about 10-80 wt %.

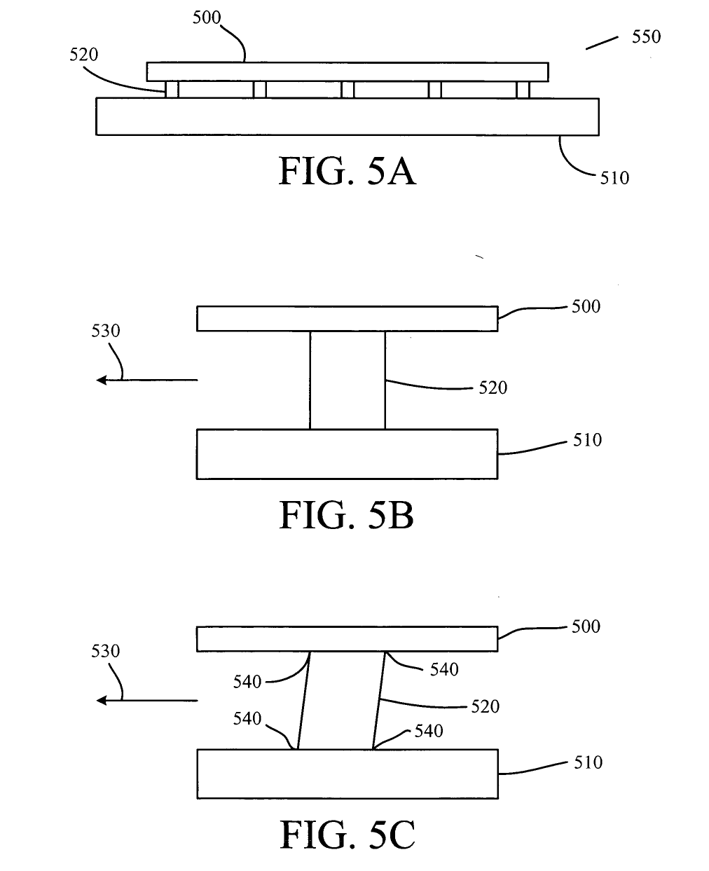

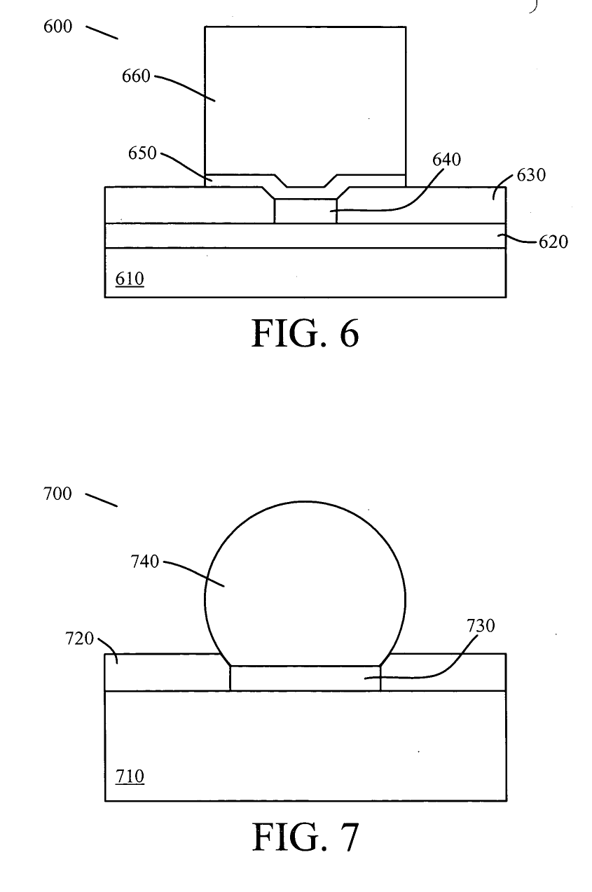

FIG. 5A illustrates a package 550 including a chip 500 connected to a substrate 510 by a conductor 520. Conductor 520 may include any suitable shape memory material as described above. The shape memory material may be incorporated in conductor 520 by any suitable technique, as will be further discussed below with reference to FIGS. 6-8.

In an embodiment, chip 500 may be a semiconductor. In another embodiment, chip 500 may include monocrystalline silicon, silicon on insulator or other suitable materials. In an embodiment, chip 500 may include layers and structures that comprise insulative, conductive, or semiconductive materials. In an embodiment, chip 500 may include transistors and metal interconnect layers and may be a functional integrated circuit. Substrate 510 may be any suitable material. As is illustrated in FIG. 5A, chip 500 may be flip-chip bonded to substrate 510. In another embodiment, a conductive solder (not shown) may be provided to connect chip 500 and substrate 510. In an embodiment, an underfill material (not shown) may be provided between chip 500 and substrate 510.

In some embodiments, chip 500 and substrate 510 may have different coefficients of thermal expansion. In such embodiments, upon heating or cooling package 550, chip 500 and substrate 510 may expand or contract at different rates. FIGS. 5B and 5C illustrate an embodiment where, upon cooling, substrate 510 contracts at a faster rate than chip 500. FIGS. 5B and 5C illustrate a portion of chip 500, a portion of substrate 510, conductor 520, potential high stress points 540, and arrow 530. Arrow 530 indicates the direction of the center of package 550. FIG. 5B illustrates package 550 at an elevated temperate and FIG. 5C illustrates package 550 after cooling. In an embodiment, FIG. 5B may illustrate a package formed at the freezing point of a solder. Upon cooling, substrate 510 may contract faster than chip 500 and may cause a stress-strain mismatch between chip 500 and substrate 510 (as indicated by the deformation of conductor 520) and potential high stress points 540. In an embodiment, the stress-strain mismatch may increase as the temperature continues to decrease.

As discussed above, the shape memory material included in conductors 520 may become more compliant when the temperature falls below characteristic temperature M_{d}. In an embodiment, M_{d} may be in the range of about 120 to 180° C. In another embodiment, M_{d} may be in the range of about 140 to 160° C. Due to the material characteristics of the shape memory material included in conductors 520, a low amount of stress may be provided at potential high stress points 540 and throughout package 550. Therefore, the shape memory material included in conductors 520 may absorb most of the deformation and may accommodate a high stress-strain mismatch between chip 500 and substrate 510. In an embodiment, there may be minimal or no damage during subsequent thermal cycles of the packaging process. Further, due to the high melting temperature of the shape memory material, the shape memory material included in conductors 520 may exhibit resistance to electromigration.

In addition, as discussed in reference to FIGS. 1 and 2, any deformation of conductors 520 less than a maximum strain may be recovered. In an embodiment, more than 1% deformation may be recovered. In an embodiment, approximately 8% deformation may be recovered. In another embodiment, approximately 1 to 6% deformation may be recovered. In another embodiment, approximately 3 to 8% deformation may be recovered. In an embodiment, no heating may be required to recover the deformation. In such embodiments, the deformation may be recovered at a temperature between Mₛ and M_{d}. In an embodiment, characteristic temperature Mₛ may be below room temperature and no heating may be required to recover a deformation.

In another embodiment, heating may be required to recover the deformation. In an embodiment, the temperature required to recover the deformation may be above M_{f}. In another embodiment, the temperature required to recover the deformation may be in the range of about 20 to 50° C. greater than Mₛ. In an embodiment, the temperature required to recover the deformation may be in the range of about 50 to 80° C. greater than Mₛ. In another embodiment, the temperature required to recover the deformation may be in the range of about 30 to 60° C. greater than Mₛ.

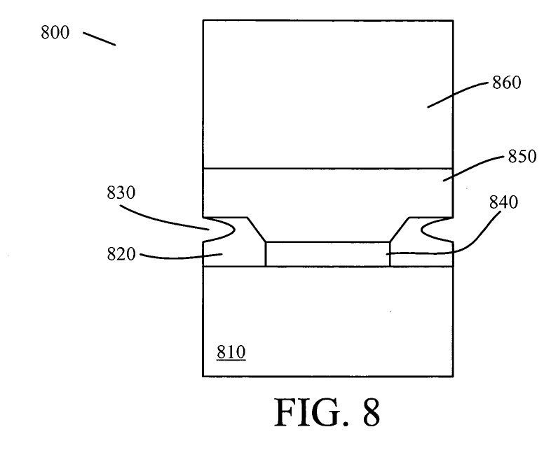

As is discussed with reference to FIGS. 6-8, a shape memory material may be incorporated in any suitable way so as to be included in conductors 520. FIG. 6 illustrates that the shape memory material may be incorporated as a bump on a chip. FIG. 7 illustrates that the shape memory material may be incorporated as a bump on a substrate. FIG. 8 illustrates that the shape memory material may be incorporated as an under bump metallurgy on a chip. Other implementations may be available.

FIG. 6 illustrates a cross sectional type view of a portion of an apparatus 600 including a chip substrate 610, interconnect layers 620, a passivation layer 630, a bond pad 640, an under bump metallurgy 650, and a bump 660.

Bump 660 may include any suitable shape memory material or any suitable composite including a shape memory material as described above. In an embodiment, bump 660 may include Nitinol, an alloy of Nickel and Titanium. In another embodiment, bump 660 may include a Copper shape memory alloy. In an embodiment, bump 660 may include a Copper shape memory alloy including Zinc. In another embodiment, bump 660 may include a Copper shape memory alloy including Aluminum.

In other embodiments, bump 660 may include a composite of two or more materials. In an embodiment, the composite may include a metal or solder with embedded shape memory material powders or fibers. In another embodiment, the composite may include a matrix metal and shape memory material powders or fibers. In various embodiments, the composite may include Copper, Tin, or Gold and shape memory material powder or fibers. In some embodiments, the shape memory powders or fibers may include Nitinol or Copper shape memory alloys. The shape memory material powders or fibers may be of any suitable weight percentage. In an embodiment, the shape memory material may be in the range of about 0-80 wt %. In another embodiment, the shape memory material may be in the range of about 40-80 wt %. In an embodiment, the shape memory material may be in the range of about 10-80 wt %.

In another embodiment, bump 660 may include a solder and imbedded shape memory material powders or fibers. The solder may be any suitable material and the shape memory material may be of any suitable weight percentage. In an embodiment, the shape memory material may be in the range of about 0-80 wt %. In another embodiment, the shape memory material may be in the range of about 40-80 wt %. In an embodiment, the shape memory material may be in the range of about 10-80 wt %.

As illustrated in FIG. 6, bump 660 may be square or rectangular in shape. However, bump 660 may be any suitable shape, such as rounded or spherical.

Chip substrate 610 may be any suitable material and may include transistors and other devices to form an integrated circuit. Interconnect layers 620 may be any suitable materials and may include metallization layers and dielectrics in order to interconnect the devices in chip substrate 610 and to connect to bond pads, such as bond pad 640. Passivation layer 630 may be any suitable material. In an embodiment, passivation layer 630 may include a polyimide. Bond pad 640 may be any suitable material and may provide a location for connecting devices in chip substrate 610 to the exterior environment. In an embodiment, bond pad 640 may include copper. Under bump metallurgy 650 may include any suitable material. In an embodiment, under bump metallurgy 650 may not be included.

Apparatus 600 may be formed by any suitable technique. In an embodiment, forming apparatus 600 may include forming an adhesion layer over passivation layer 630 and bond pad 640, photolithography resist patterning, electroplating bump 660, and etching the resist and adhesion layer. Other techniques, such as sputter deposition of a shape memory material, may be available. In an embodiment, bump 660 may be formed by electroplating using shape memory material powders suspended in an electrolyte including Copper where the shape memory material powders may sediment during the Copper bump plating. In other embodiments, bump 660 may be formed by printing or ink injection. In such embodiments, a shape memory material may be mixed with solder powder and the mixture may be printed together and bumps may be formed by reflow.

In an embodiment, apparatus 600 may be flip-chip bonded to a substrate using any suitable technique. In an embodiment, apparatus 600 may be flip-chip bonded to a substrate using a solder. In another embodiment, bonding apparatus 600 to a substrate may include providing an underfill material between apparatus 600 and a substrate.

FIG. 7 illustrates a cross sectional type view of a portion of an apparatus 700 including a package substrate 710, resist 720, a bond pad 730, and a bump 740.

Bump 740 may include any suitable shape memory material or any suitable composite including a shape memory material as described above. In an embodiment, bump 740 may include Nitinol, an alloy of Nickel and Titanium. In another embodiment, bump 740 may include a Copper shape memory alloy. In an embodiment, bump 740 may include a Copper shape memory alloy including Zinc. In another embodiment, bump 740 may include a Copper shape memory alloy including Aluminum.

In other embodiments, bump 740 may include a composite of two or more materials. In an embodiment, the composite may include a metal or solder with embedded shape memory material powders or fibers. In another embodiment, the composite may include a matrix metal and shape memory material powders or fibers. In various embodiments, the composite may include Copper, Tin, or Gold and shape memory material powder or fibers. In some embodiments, the shape memory powders or fibers may include Nitinol or Copper shape memory alloys. The shape memory material powders or fibers may be of any suitable weight percentage. In an embodiment, the shape memory material may be in the range of about 0-80 wt %. In another embodiment, the shape memory material may be in the range of about 40-80 wt %. In an embodiment, the shape memory material may be in the range of about 10-80 wt %.

In another embodiment, bump 740 may include a solder and imbedded shape memory material powders or fibers. The solder may be any suitable material and the shape memory material may be of any suitable weight percentage. In an embodiment, the shape memory material may be in the range of about 0-80 wt %. In another embodiment, the shape memory material may be in the range of about 40-80 wt %. In an embodiment, the shape memory material may be in the range of about 10-80 wt %.

As illustrated in FIG. 7, bump 740 may be rounded or spherical in shape. However, bump 740 may be any suitable shape, such as squared off or rectangular.

Package substrate 710 may be any suitable material and may include metallization layers to facilitate electrical connections to other circuitry. Resist 720 may be any suitable material. Bond pad 730 may be any suitable material and may provide a location for connecting electrical circuitry to a chip. In an embodiment, bond pad 640 may include copper.

Apparatus 700 may be formed by any suitable technique. In some embodiments, bump 740 may be formed by printing or ink injection. In such embodiments, a shape memory material may be mixed with solder powder and the mixture may be printed together and bumps may be formed by reflow.

In an embodiment, apparatus 700 may be flip-chip bonded to a chip using any suitable technique. In an embodiment, apparatus 700 may be flip-chip bonded to a chip using a solder. In another embodiment, bonding apparatus 700 to a chip may include providing an underfill material.

FIG. 8 illustrates an apparatus 800 including a chip substrate 810, a passivation layer 820, overhang areas 830, a bond pad 840, a under bump metallurgy 850, and a bump 860.

Under bump metallurgy 850 may include any suitable shape memory material or any suitable composite including a shape memory material as described above. In an embodiment, under bump metallurgy 850 may include Nitinol, an alloy of Nickel and Titanium. In another embodiment, under bump metallurgy 850 may include a Copper shape memory alloy. In an embodiment, under bump metallurgy 850 may include a Copper shape memory alloy including Zinc. In another embodiment, under bump metallurgy 850 may include a Copper shape memory alloy including Aluminum.

In other embodiments, under bump metallurgy 850 may include a composite of two or more materials. In an embodiment, the composite may include a metal or solder with embedded shape memory material powders or fibers. In another embodiment, the composite may include a matrix metal and shape memory material powders or fibers. In various embodiments, the composite may include Copper, Tin, or Gold and shape memory material powder or fibers. In some embodiments, the shape memory powders or fibers may include Nitinol or Copper shape memory alloys. The shape memory material powders or fibers may be of any suitable weight percentage. In an embodiment, the shape memory material may be in the range of about 0-80 wt %. In another embodiment, the shape memory material may be in the range of about 40-80 wt %. In an embodiment, the shape memory material may be in the range of about 10-80 wt %.

In another embodiment, under bump metallurgy 850 may include a solder and imbedded shape memory material powders or fibers. The solder may be any suitable material and the shape memory material may be of any suitable weight percentage. In an embodiment, the shape memory material may be in the range of about 0-80 wt %. In another embodiment, the shape memory material may be in the range of about 40-80 wt %. In an embodiment, the shape memory material may be in the range of about 10-80 wt %.

Chip substrate 810 may be any suitable material and may include transistors, other devices, and interconnect layers to form an integrated circuit. Passivation layer 820 may be any suitable material. In an embodiment, passivation layer 820 may include a polyimide. Passivation layer 820 may include overhang areas 830 caused by etching. In an embodiment, overhang areas 830 may be around the perimeter of bond pad 840. In some embodiments, overhang areas 830 may be stress focus points. In another embodiment, passivation layer 820 may not include overhang areas 830. Bond pad 840 may be any suitable material and may provide a location for connection of devices in chip substrate 810 to the exterior environment. In an embodiment, bond pad 840 may include copper.

Apparatus 800 may be formed by any suitable technique. In an embodiment, under bump metallurgy 850 may be formed by a deposition including sputtering, patterning, and etching. In another embodiment, under bump metallurgy 850 may include Nitinol formed by depositing alternating layers of Nickel and Titanium and annealing the stack at a temperature in the range of about 350-450° C.

In an embodiment, apparatus 800 may be flip-chip bonded to a substrate using any suitable technique. In an embodiment, apparatus 800 may be flip-chip bonded to a substrate using a solder. In another embodiment, bonding apparatus 800 to a substrate may include providing an underfill material.

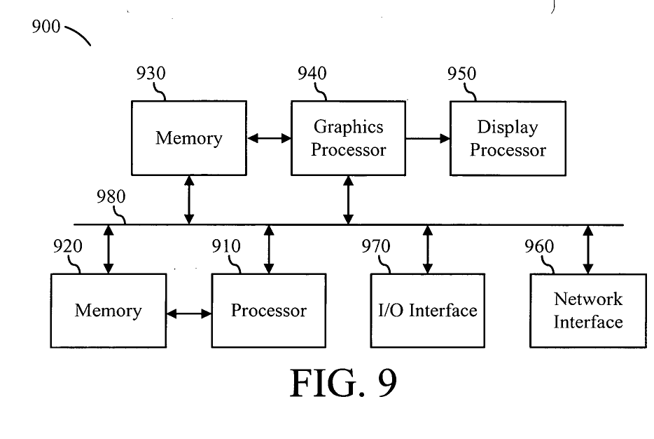

As illustrated in FIG. 9, any of the shape memory materials discussed above may be incorporated into a system 900. System 900 may include a processor 910, a memory 920, a memory 930, a graphics processor 940, a display processor 950, a network interface 960, an I/O interface 970, and a communication bus 980. In any manner as described above, any of the components in system 900 may include shape memory materials to bond a component chip or die to a substrate or motherboard. In an embodiment, processor 910 may include shape memory materials. In another embodiment, graphics processor 940 may include shape memory materials. In another embodiment, memory 920 may be a volatile memory component and may include shape memory materials. A large number of combinations of components including shape memory materials may be available.

Reference throughout this specification to “one embodiment” or “an embodiment” means that a particular feature, structure, material, or characteristic described in connection with the embodiment is included in at least one embodiment of the invention. Thus, the appearances of the phrases “in one embodiment” or “in an embodiment” in various places throughout this specification are not necessarily referring to the same embodiment of the invention. Furthermore, the particular features, structures, materials, or characteristics may be combined in any suitable manner in one or more embodiments.

It is to be understood that the above description is intended to be illustrative, and not restrictive. Many other embodiments will be apparent to those of ordinary skill in the art upon reviewing the above description. The scope of the invention should, therefore, be determined with reference to the appended claims, along with the full scope of equivalents to which such claims are entitled.

What is claimed is:

1. An apparatus comprising:
a die coupled to a substrate by a conductor including a shape memory material.

2. The apparatus of claim 1, wherein the shape memory material comprises Nitinol.

3. The apparatus of claim 1, wherein the shape memory material comprises a Copper shape memory alloy.

4. The apparatus of claim 1, wherein the conductor comprises a bump on the die.

5. The apparatus of claim 1, wherein the conductor comprises a bump on the substrate.

6. The apparatus of claim 1, wherein the conductor comprises an under bump metallurgy on the die.

7. The apparatus of claim 1, wherein the conductor comprises a metal and the shape memory material is a powder mixed in the metal.

8. The apparatus of claim 7, wherein the weight percentage of the shape memory material in the metal is in the range of about 40-80 wt %.

9. The apparatus of claim 1, wherein the conductor comprises a solder and the shape memory material is a powder mixed in the solder.

10. The apparatus of claim 1, wherein the die is flip-chip coupled to the substrate.

11. The apparatus of claim 1, further comprising:
an underfill material between the die and the substrate.

12. A method comprising:
attaching a die to a substrate with a conductor that includes a shape memory material to form a package.

13. The method of claim 12, wherein attaching the die includes cooling the package such that the substrate contracts faster than the die and the shape memory material reduces a stress.

14. The method of claim 12, wherein attaching the die includes deforming the conductor by more than 1% and recovering the deformation.

15. The method of claim 14, wherein recovering the deformation includes heating the package to a temperature in the range of about 30 to 60° C. above a characteristic temperature, Mₛ, of the shape memory material.

16. The method of claim 12, wherein attaching the die includes deforming the conductor by an amount in the range of about 1 to 6% and recovering the deformation.

17. The method of claim 12, wherein attaching the die includes deforming the conductor by approximately 8% and recovering the deformation.

18. The method of claim 12, wherein the shape memory material comprises Nitinol.

19. The method of claim 12, wherein the shape memory material comprises a Copper shape memory alloy.

20. The method of claim 12, wherein the conductor comprises a bump on the die.

21. The method of claim 12, wherein the conductor comprises a bump on the substrate.

22. The method of claim 12, wherein the conductor comprises an under bump metallurgy on the die.

23. The method of claim 12, wherein the conductor comprises a metal and the shape memory material is a powder mixed in the metal.

24. The method of claim 12, wherein the conductor comprises a solder and the shape memory material is a powder mixed in the solder.

25. A system comprising:
a microprocessor coupled to a substrate by a conductor including a shape memory material; and
a display processor.

26. The system of claim 25, further comprising:
a volatile memory component.
